(19) United States
(12) Patent Application Publication
(10) Pub. No.: US 2014/0337676 A1
(43) Pub. Date: Nov. 13, 2014

(54) Systems and Methods for Processing Data With Microcontroller Based Retry Features

(71) Applicant: LSI Corporation, San Jose, CA (US)

(72) Inventors: Johnson Yen, Fremont, CA (US); Ngok Ying Chu, Los Altos, CA (US)

(73) Assignee: LSI Corporation, San Jose, CA (US)

(21) Appl. No.: 13/947,768

(22) Filed: Jul. 22, 2013

Related U.S. Application Data
(60) Provisional application No. 61/821,647, filed on May 9, 2013.

(51) Int. Cl. H03M 13/37; H03M 13/41

(52) U.S. Cl. CPC H03M 13/37; H03M 13/41
USPC 714/712

(57) ABSTRACT

A data processing system is disclosed including a data detector, a data decoder and a microcontroller. The data detector is operable to apply a data detection algorithm to generate detected values for data sectors. The data decoder is operable to apply a data decode algorithm to a decoder input derived from the detected values to yield decoded values. The microcontroller is operable to configure the data detector and the data decoder to apply the data detection algorithm and the data decode algorithm.

### CROSS REFERENCE TO RELATED APPLICATIONS

The present application claims priority to (is a non-provisional of) U.S. Pat. App. No. 61/821,647, entitled “Systems and Methods for Processing Data With Microcontroller Based Retry Features”, and filed May 9, 2013 by Yen et al, the entirety of which is incorporated herein by reference for all purposes.

### FIELD OF THE INVENTION

Various embodiments of the present invention provide systems and methods for processing data, and more particularly to systems and methods for processing data in a read channel with retry features controlled by an embedded microcontroller.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Errors can be detected and corrected in a read channel. When errors are not corrected with normal error correction procedures, retry features may be needed to correct stubborn errors. Such retry features can be complex and difficult to implement, test, and control.

### BRIEF SUMMARY

Embodiments of the present invention provide a read channel with an embedded microcontroller for controlling data processing, including error correction retry features. A data processing system is disclosed including a data detector, a data decoder and a microcontroller. The data detector is operable to apply a data detection algorithm to generate detected values for data sectors. The data decoder is operable to apply a data decode algorithm to a decoder input derived from the detected values to yield decoded values. The microcontroller is operable to configure the data detector and the data decoder to apply the data detection algorithm and the data decode algorithm.

This summary provides only a general outline of some embodiments according to the present invention. Many other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a block diagram of a read channel with an embedded microcontroller in accordance with some embodiments of the present invention;

FIG. 2 depicts a flow diagram of controlling a data processing operation with an embedded microcontroller in accordance with some embodiments of the present invention;

FIG. 3 depicts a flow diagram of controlling a retry feature in a data processing operation with an embedded microcontroller in accordance with some embodiments of the present invention;

FIG. 4 depicts a storage system including a read channel with an embedded microcontroller in accordance with some embodiments of the present invention; and

FIG. 5 depicts a wireless communication system including a read channel with an embedded microcontroller in accordance with some embodiments of the present invention.

### DETAILED DESCRIPTION OF THE INVENTION

Embodiments of the present invention are related to controlling data processing in a read channel with an embedded microcontroller, including in some instances controlling error correction retry features. A read channel with embedded microcontroller is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

The read channel performs data detection and decoding functions to detect the correct values of data that is received or retrieved from a transmission channel or storage medium, and the embedded microcontroller provides flexibility and programmability of either or both normal operation and retry features. In some embodiments, the embedded microcontroller also allows the creation of workaround solutions in case of design bugs in the read channel, without having to modify the hardware.

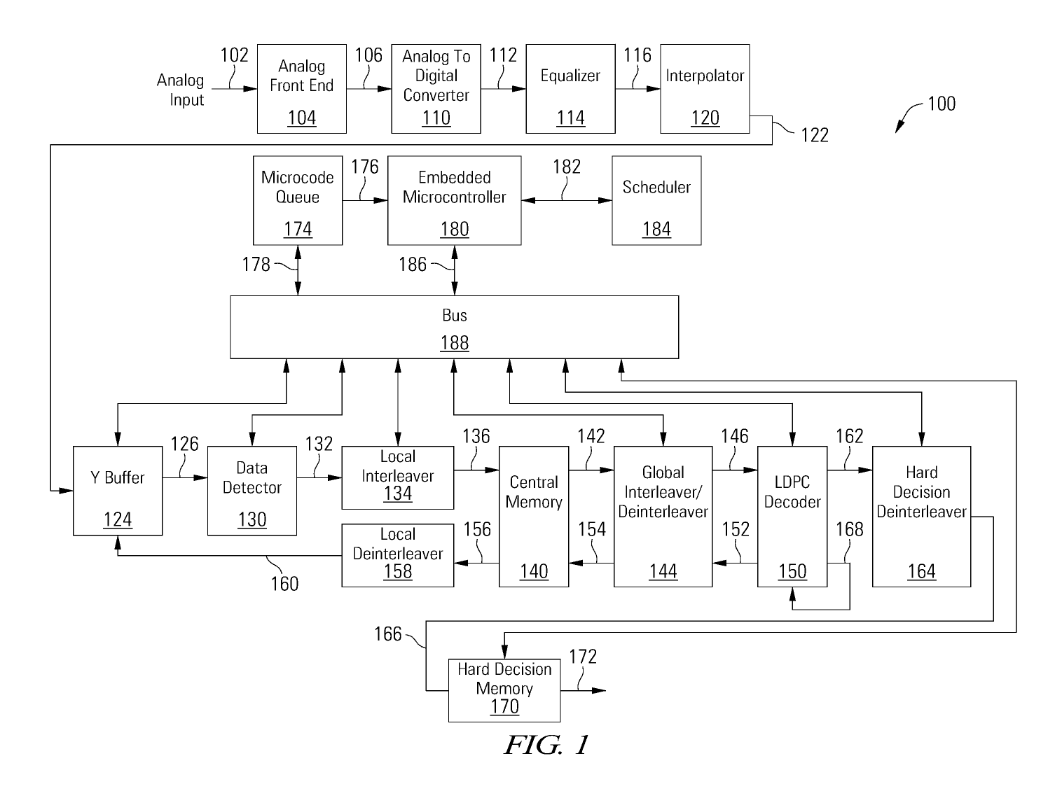

Turning to FIG. 1, a read channel 100 with an embedded microcontroller 180 is used to process an analog signal 102 and to retrieve user data bits from the analog signal 102 without errors. The embedded microcontroller 180 controls either or both the normal data processing and retry features applied when normal data processing fails to retrieve user data bits without errors. In some cases, analog signal 102 is derived from a read/write head assembly in a magnetic storage medium. In other cases, analog signal 102 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 102 may be derived.

The read channel 100 includes an analog front end 104 that receives and processes the analog signal 102. Analog front end 104 may include, but is not limited to, an analog filter and an amplifier circuit as are known in the art. Based upon the disclosure provided herein, one of ordinary skill in the art will recognize a variety of circuitry that may be included as part of analog front end 104. In some cases, the gain of a variable gain amplifier included as part of analog front end 104 may be modifiable, and the cutoff frequency and boost of an analog filter included in analog front end 104 may be modifiable. Analog front end 104 receives and processes the analog signal 102, and provides a processed analog signal 106 to an analog to digital converter 110.

Analog to digital converter 110 converts processed analog signal 106 into a corresponding series of digital samples 112. Analog to digital converter 110 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 112 are provided to an equalizer 114. Equalizer 114 applies an equalization algorithm to digital samples 112 to yield an equalized output 116. In some embodiments of the present invention, equalizer 114 is a digital finite impulse response filter circuit as is known in the art. Equalizer 114 ensures that equalized output 116 has the desired spectrum for data detector 130.

The equalized output 116 is provided to an interpolator 120, which performs timing and tracking functions to remove radial incoherence in equalized output 116 and yielding interpolated output 122. The interpolator 120 may include one interpolation circuit or a bank of interpolation circuits operating at different phase offsets, interpolating between samples in equalized output 116 to overcome the quick phase changes and signal loss associated with radial incoherence. Interpolator 120 interpolates between samples in the equalized output 116 to yield time-aligned samples in interpolated output 122 in order to align the received samples from analog signal 102 with the expected samples or Y ideals. Based upon the disclosure provided herein, one of ordinary skill in the art will recognize a variety of interpolation architectures and/or other numbers of interpolator circuits and phase offsets that may be used in relation to different embodiments of the present invention.

Equalized output 122 is provided to a sample buffer 124 that includes sufficient memory to maintain one or more codewords until processing of that codeword is completed through a data detector 130 and a data decoder 150 including, where warranted, multiple “global iterations” defined as passes through both data detector 130 and data decoder 150 and/or “local iterations” defined as passes through data decoder 150 during a given global iteration. The digital data provided to sample buffer 124 in read channel 100 may be provided by components such as the analog front end 104, analog to digital converter 110, equalizer 114 and interpolator 120, or by other or additional circuits performing functions such as DC compensation, cancellation of inter-track interference, or other functions. In other embodiments, digital data provided to sample buffer 124 may be derived from other sources, including digital data sources.

Buffered data 126 from sample buffer 124 is provided to a data detector 130 which applies a data detection algorithm to buffered data 126 to detect the correct values of data bits or symbols in buffered data 126, resulting in a detected output 132. In some embodiments of the present invention, data detector 130 is a Viterbi algorithm data detector circuit as are known in the art. In other embodiments of the present invention, data detector 130 is a maximum a posteriori data detector circuit as are known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, a Viterbi detection algorithm or Viterbi algorithm detector circuit that operates on wide bi-phase encoded user data. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention. Data detector 130 is started based upon availability of a data set in sample buffer 124 from interpolator 120 or another source, or from a central memory circuit 140.

Upon completion, data detector 130 provides a detected output 132 which includes soft data. As used herein, the phrase “soft data” is used in its broadest sense to mean reliability data with each instance of the reliability data indicating a likelihood that a corresponding bit position or group of bit positions has been correctly detected. In some embodiments of the present invention, the soft data or reliability data is log likelihood ratio data as is known in the art. Detected output 132 is provided to a local interleaver 134. Local interleaver 134 is operable to shuffle sub-portions (i.e., local chunks) of the data set included as detected output 132 and provides an interleaved codeword 136 that is stored to central memory 140. Local interleaver 134 may be any circuit known in the art that is capable of shuffling data sets to yield a re-arranged data set.

Once a data decoder 150 is available, a previously stored interleaved codeword 142 is accessed from central memory 140 and globally interleaved by a global interleaver/deinterleaver circuit 144. Global interleaver/deinterleaver circuit 144 may be any circuit known in the art that is capable of globally rearranging codewords. Global interleaver/deinterleaver circuit 144 provides a decoder input 146 to data decoder 150.

Data decoder 150 applies a data decoding algorithm to decoder input 146 in an attempt to recover originally written data. The result of the data decoding algorithm is provided as a decoded output 152. Similar to detected output 132, decoded output 152 may include both hard decisions and soft decisions. Data decoder 150 may be any data decoder circuit known in the art that is capable of applying a decoding algorithm to a received input. Data decoder 150 may be, but is not limited to, a low density parity check decoder circuit or a Reed Solomon decoder circuit as are known in the art. Based upon the disclosure provided herein, one of ordinary skill in the art will recognize a variety of data decoder circuits that may be used in relation to different embodiments of the present invention. Where the original data is recovered (i.e., the data decoding algorithm converges) or a timeout condition occurs, data decoder 150 provides the result of the data decoding algorithm as a data output 162.

Data output 162 is provided to a hard decision deinterleaver 164 which is operable to reverse the global interleaving applied by global interleaver/deinterleaver circuit 144, yielding hard decisions 166 which are stored in hard decision memory 170 before being yielded as data output 172, or a representation of the original data that was encoded and stored or transmitted.

One or more iterations through the combination of data detector 130 and data decoder 150 may be made in an effort to converge on the originally written data set. As mentioned above, processing through both the data detector 130 and the data decoder 150 is referred to as a “global iteration”. For the first global iteration, data detector 130 applies the data detection algorithm without guidance from a decoded output. For subsequent global iterations, data detector circuit 130 applies the data detection algorithm to buffered data 126 as guided by decoded output 152. Where the data decoding algorithm as applied by data decoder 150 fails to converge, decoder output 152 from data decoder 150 is transferred back to central memory circuit 140 via global interleaver/deinterleaver circuit 144. Prior to storage of the decoder output 152 to central memory circuit 140, the decoder output 152 is globally deinterleaved to yield a globally deinterleaved output 154 that is stored to central memory circuit 140. The global deinterleaving reverses the global interleaving earlier applied to the interleaved codeword 142 to yield the decoder input 146. Once data detector 130 is available, a previously stored deinterleaved output 156 is accessed from central memory circuit 140 and locally deinterleaved by a local deinterleaver circuit 158. Local deinterleaver circuit 158 rearranges the globally deinterleaved output 154 to reverse the shuffling originally performed by local interleaver circuit 134. A resulting deinterleaved output 160 is provided to data detector 130 where it is used to guide subsequent detection of a corresponding data set received as interpolated output 122 from interpolator 120.

During each global iteration it is possible for data decoder 150 to make one or more local iterations including application of the data decoding algorithm to decoder input 146. For the first local iteration, data decoder 150 applies the data decoder algorithm without guidance from a decoded output 136. For subsequent local iterations, data decoder 150 applies the data decoding algorithm to decoder input 146 as guided by a previous decoded output 168. In some embodiments of the present invention, a default of ten local iterations is allowed for each global iteration.

A scheduler 184 is provided in some embodiments to control global detection/decoding iterations in the read channel 100, for example controlling data flow from sample buffer 124 to data detector 130, specifying the data sector or other data block to be processed, configuring and initiating decoding operations by data decoder 150, triggering retry features when data fails to converge in data decoder 150 after a number of global decoding iterations, etc. In some embodiments, the scheduler 184 controls the operation of the read channel 100 by configuring control registers in one or more of sample buffer 124, data detector 130, local interleaver 134, global interleaver/deinterleaver circuit 144, data decoder 150 and hard decision deinterleaver 164 with scheduling commands 182.

An embedded microcontroller 180 controls the read channel 100 by configuring the scheduler 184 and programmably selecting, coordinating and controlling normal data processing and retry features. In other embodiments, the embedded microcontroller 180 performs the functions of the scheduler 184, replacing the scheduler 184 rather than operating with the scheduler 184. The embedded microcontroller 180 can be a simple architecture such as, but not limited to, an 8051 microcontroller or other known architecture, or can be a more complex known architecture or a custom architecture. In some embodiments, the embedded microcontroller 180 is included on a single integrated circuit along with some or all of the other circuits of the read channel 100, such as the data detector 130 and data decoder 150. In other embodiments, a microcontroller used to control the read channel 100 is an external device coupled to other circuits of the read channel 100 in a system. Based upon the disclosure provided herein, one of ordinary skill in the art will recognize a variety of microcontrollers that may be used in relation to different embodiments of the present invention.

A microcode queue 174 provides program instructions 176 to embedded microcontroller 180 to configure the embedded microcontroller 180 for operation. The embedded microcontroller 180 executes the microcode in microcode queue 174. In some embodiments, the microcode queue 174 is programmable and can receive new code after manufacturing or during operation. This provides flexibility and programmability for the read channel 100, for example to debug the read channel 100, to add new functionality, to add workarounds for hardware problems, and optimizations for normal processing or retry features.

A bus 186 is provided in some embodiments to carry configuration information 186 from embedded microcontroller 180 to elements of the read channel 100 such as, but not limited to, sample buffer 124, data detector 130, local interleaver 134, global interleaver/deinterleaver circuit 144, data decoder 150 and hard decision deinterleaver 164. Bus 188 may also carry scheduling commands 182 from scheduler 184 to elements of the read channel 100 such as, but not limited to, sample buffer 124, data detector 130, local interleaver 134, global interleaver/deinterleaver circuit 144, data decoder 150 and hard decision deinterleaver 164.

Bus 188 may use any suitable architecture and protocol, such as, but not limited to, a micro-channel architecture. In other embodiments, other communication structures are used in place of bus 188, such as a multi-port random access memory. Based upon the disclosure provided herein, one of ordinary skill in the art will recognize a communication circuits that may be used in relation to different embodiments of the present invention to connect the embedded microcontroller 180 with other elements of the read channel 100.

The microcode queue 174 can also contain register settings 178 to be provided directly to one or more elements of the read channel 100 through bus 188 such as, but not limited to, the sample buffer 124, local interleaver 134, global interleaver/deinterleaver circuit 144, data decoder 150 and hard decision deinterleaver 164.

The embedded microcontroller 180 can flexibly control both normal processing and the complex, lengthy retry features. The embedded microcontroller 180 controls the operation mode of the read channel 100, kicks off operations, and accesses status registers. This allows for enhancement of existing retry features and for new retry features to be added after hardware manufacturing, e.g., after tapeout. This also provides a testing platform to evaluate the performance of retry modes. The embedded microcontroller 180 can directly access memories in the read channel 100 such as, but not limited to, sample buffer 124, hard decision memory 170, and memories in scheduler 184 and data decoder 150. The embedded microcontroller 180 can also program execution units in the read channel 100 such as, but not limited to, the data detector 130, local interleaver 134 and local deinterleaver circuit 158, global interleaver/deinterleaver circuit 144, data decoder 150 and hard decision deinterleaver 164. Command queues are used in some embodiments to send commands from the embedded microcontroller 180 to the execution units. The command queues may be located in microcode queue 174 or in individual execution units or any other suitable location.

The embedded microcontroller 180 can be used to control any retry features in the read channel 100, such as, but not limited to, No SyncMark Retry (NSM) and Targeted Symbol Flipping (TSF). A sync mark is a pattern that specifies the starting location of user data to be processed. No SyncMark Retry is an error recovery feature that attempts to recover data when no sync mark is found or when a sync mark is erroneously identified at an incorrect location. In this recovery feature, Y samples are stored in sample buffer 124, and the embedded microcontroller 180 has access to sample buffer 124. The embedded microcontroller 180 arranges the data in sample buffer 124 according to a forced sync mark location within a window on the data, and issues a command for the data detector 130 and data decoder 150 to start decoding the data. If the data converges in the data decoder 150, the recovery has succeeded and the resulting hard decisions are provided at data output 172. If the data fails to converge, the embedded microcontroller 180 again moves the data within the window in sample buffer 124 and initiates data decoding. The process continues until either the data converges, or all locations within the window have been attempted for the forced sync mark without the data converging. In the latter case, unconverged data can be provided at data output 172, along with an indication that the data failed to converge. The window for No SyncMark Retry operations can be defined by a pair of registers containing the start position and end position, and can be programmed by the embedded microcontroller 180 in some embodiments to customize the No SyncMark Retry feature.

In Targeted Symbol Flipping, the input hard decision and soft values to the data decoder 150 for selected bits or symbols are changed in an attempt to cause the data decoder 150 to converge. For example, in a non-binary low density parity check data decoder 150 having a

Galois Field with four elements, the input values of the symbols being flipped are changed to different elements of the Galois Field by adding 1, 2 or 3 to the hard decision. The term “targeted” is used herein to indicate that the bits or symbols to be flipped are selectively chosen from unsatisfied check pools, sets of check nodes for which parity check constraints are violated. The variable nodes connected to each check node for which parity check constraints are violated are members of the unsatisfied check pool. In some embodiments, parity check constraints are violated if any check node fails a parity check. If the data decoder 150 fails to converge during normal decoding operations, the embedded microcontroller 180 controls the flipping of one or more selected symbols and the repetition of decoding iterations until the decoding converges or until it is determined that targeted symbol flipping has failed, for example, when all possible bits or symbols have been flipped without resulting in data convergence.

The embedded microcontroller 180 controls other retry features in some embodiments, such as, but not limited to, bit selective scaling (BSS), extrinsic LLR adjusting or parity forcing, dynamic vscaling in data detector 130, dynamic scaling/offset in data decoder 150, etc.

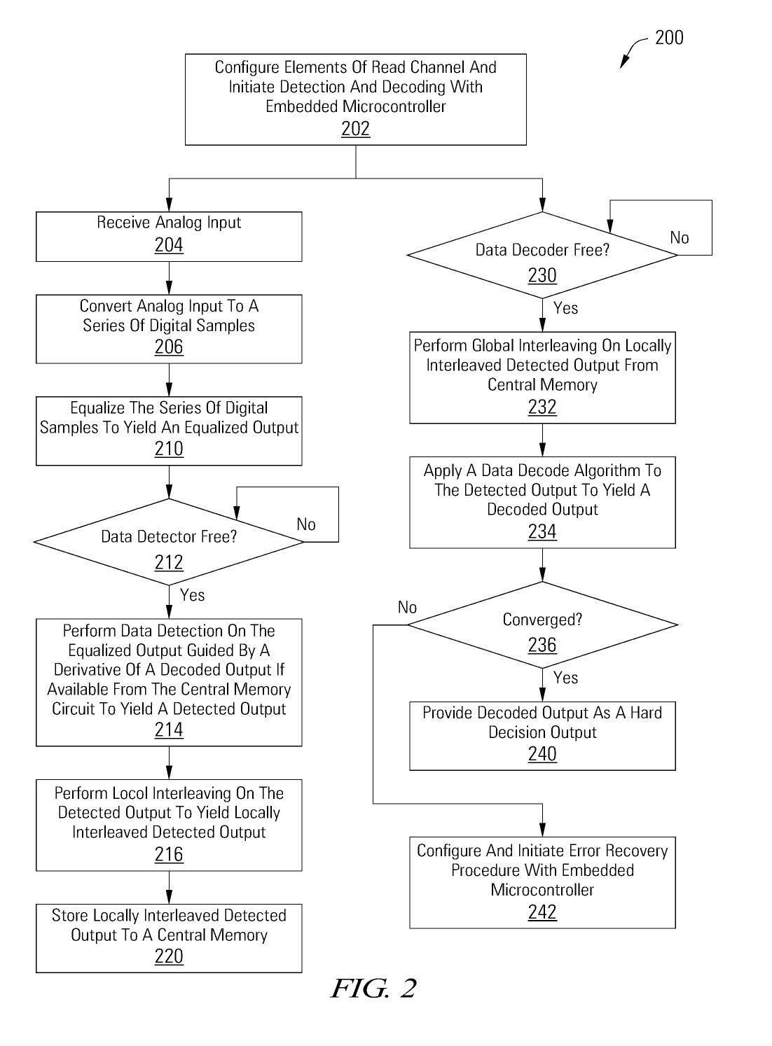

Turning to FIG. 2, a flow diagram 200 depicts an operation for controlling a data processing operation with an embedded microcontroller in accordance with some embodiments of the present invention. Following flow diagram 200, elements of a read channel are configured and detection and decoding are initiated using an embedded microcontroller. (Block 202) An analog input is received. (Block 204) The analog input may be derived from, for example, a storage medium or a data transmission channel. Based upon the disclosure provided herein, one of ordinary skill in the art will recognize a variety of sources of the analog input. The analog input is converted to a series of digital samples. (Block 206) This conversion may be done using an analog to digital converter circuit or system as are known in the art. Of note, any circuit known in the art that is capable of converting an analog signal into a series of digital values representing the received analog signal may be used. The resulting digital samples are equalized to yield an equalized output. (Block 210) In some embodiments of the present invention, the equalization is done using a digital finite impulse response circuit as are known in the art. Based upon the disclosure provided herein, one of ordinary skill in the art will recognize a variety of equalizer circuits that may be used in place of such a digital finite impulse response circuit to perform equalization in accordance with different embodiments of the present invention. Additional processing is performed in some embodiments, such as, but not limited to, interpolating between samples, cancelling inter-track interference, performing DC cancellation, etc.

It is determined whether a data detector is available. (Block 212) Where a data detector is available, a data detection algorithm is applied to the equalized output guided by a data set derived from a decoded output where available (e.g., the second and later iterations through the data detector circuit and the data decoder circuit) from a central memory to yield a detected output. (Block 214) In some embodiments of the present invention, the data detection algorithm is a Viterbi algorithm as is known in the art. In other embodiments of the present invention, the data detection algorithm is a maximum a posteriori data detector circuit as is known in the art. The data set derived from the decoded output maybe a de-interleaved version of the decoded data set. The detected output is locally interleaved to yield a locally interleaved detected output. (Block 216) The locally interleaved detected output is stored to the central memory to await processing by a data decoder. (Block 220)

In parallel to the previously discussed data detection processing, it is determined whether a data decoder is available. (Block 230) Where the data decoder circuit is available, a global interleaving process is performed on the locally interleaved detected output from the central memory. (Block 232) A data decode algorithm is applied to the globally interleaved data to yield a decoded output. (Block 234) In some embodiments, the data decode algorithm is a low density parity check algorithm. It is determined whether the decoded output converged. (Block 236) In a low density parity check decoder, convergence occurs where all of the parity checks applied as part of applying the low density parity check decoding algorithm are satisfied, resulting in a syndrome of 0. Where the decoded output converged, the decoded output is provided as a hard decision output. (Block 240)

Where the decoded output failed to converge after a particular number of local and global decoding iterations, one or more error recovery procedures are configured and initiated with an embedded microcontroller. (Block 242)

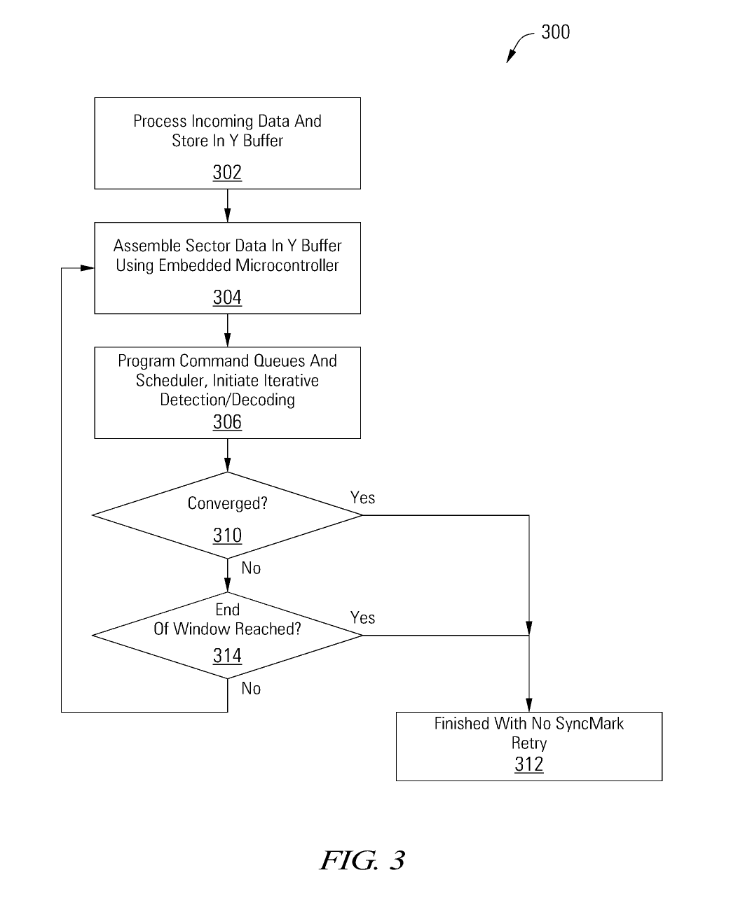

Turning to FIG. 3, a flow diagram 300 depicts an operation for controlling a No SyncMark Retry feature in a data processing operation with an embedded microcontroller in accordance with some embodiments of the present invention. Following flow diagram 300, incoming data is processed and stored in a Y buffer. (Block 302) The analog input may be derived from, for example, a storage medium or a data transmission channel. Processing may include, but is not limited to, techniques such as amplification, filtering, analog to digital conversion, equalization, DC compensation, interpolation, inter-track interference cancellation, etc. Data is assembled as a sector in the Y buffer using an embedded microcontroller. (Block 304) Command queues and a scheduler are programmed, and iterative detection/decoding is initiated. (Block 306) Programming and initiation are performed by an embedded microcontroller, which can itself be programmed to customize the retry operation. It is determined whether the sector converged. (Block 310) If so, the No SyncMark Retry operation is complete. (Block 312) The converged data can be output or otherwise used. If the sector as assembled by the embedded microcontroller failed to converge, it is determined whether the end of a window is reached. (Block 314) The window establishes a range of data in the Y buffer to be processed using the No SyncMark Retry feature, with a number of possible sectors being assembled using the data within the window by the embedded microcontroller. If the end of the window is reached, the No SyncMark Retry operation is complete. (Block 312) Although the data failed to converge, the unconverged data can be output, along with an indication of the failure to converge. If the end of the window has not been reached, the process continues with the embedded microcontroller assembling another sector. (Block 304)

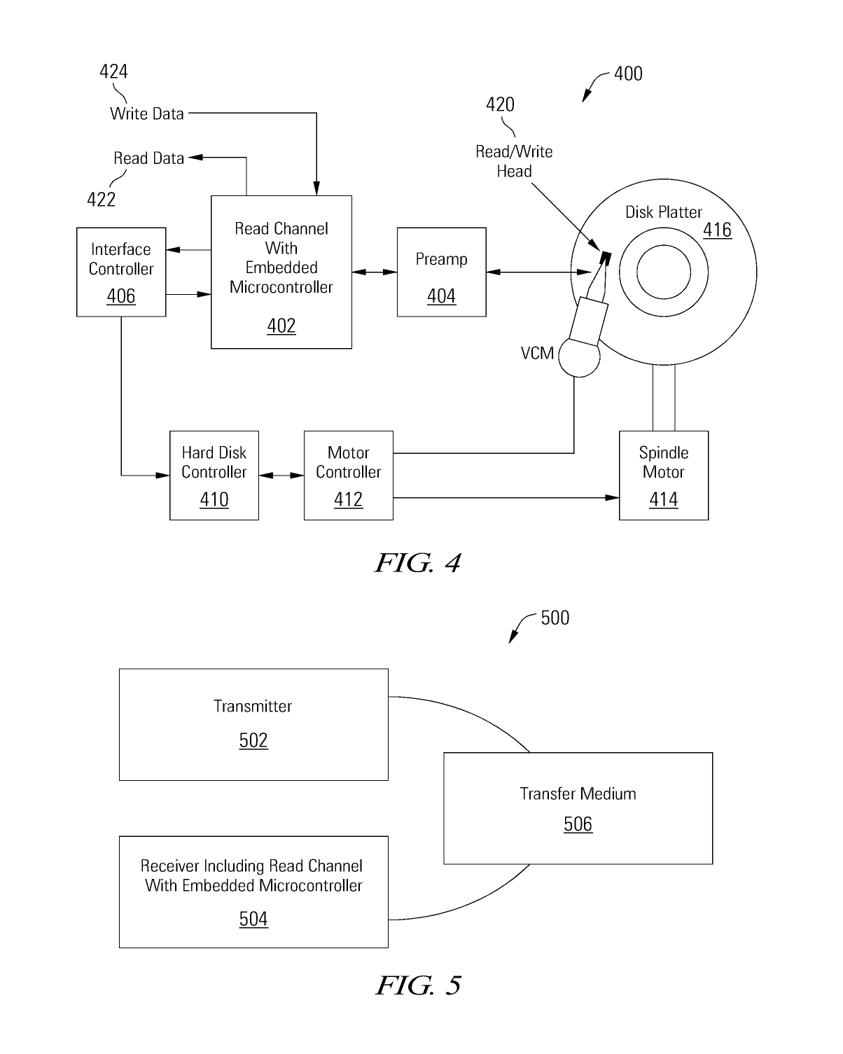

Although the read channel with embedded microcontroller is not limited to any particular application, several examples of applications are presented in FIGS. 4 and 5 that benefit from embodiments of the present invention. Turning to FIG. 4, a storage system 400 is illustrated as an example application of a read channel with embedded microcontroller in accordance with some embodiments of the present invention. The storage system 400 includes a read channel circuit 402 with a read channel with embedded microcontroller in accordance with some embodiments of the present inventions. Storage system 400 may be, for example, a hard disk drive. Storage system 400 also includes a preamplifier 404, an interface controller 406, a hard disk controller 410, a motor controller 412, a spindle motor 414, a disk platter 416, and a read/write head assembly 420. Interface controller 406 controls addressing and timing of data to/from disk platter 416. The data on disk platter 416 consists of groups of magnetic signals that may be detected by read/write head assembly 420 when the assembly is properly positioned over disk platter 416. In one embodiment, disk platter 416 includes magnetic signals recorded in accordance with either a longitudinal or a perpendicular recording scheme.

In a typical read operation, read/write head assembly 420 is accurately positioned by motor controller 412 over a desired data track on disk platter 416. Motor controller 412 both positions read/write head assembly 420 in relation to disk platter 416 and drives spindle motor 414 by moving read/write head assembly 420 to the proper data track on disk platter 416 under the direction of hard disk controller 410. Spindle motor 414 spins disk platter 416 at a determined spin rate (RPMs). Once read/write head assembly 420 is positioned adjacent the proper data track, magnetic signals representing data on disk platter 416 are sensed by read/write head assembly 420 as disk platter 416 is rotated by spindle motor 414. The sensed magnetic signals are provided as a continuous, minute analog signal representative of the magnetic data on disk platter 416. This minute analog signal is transferred from read/write head assembly 420 to read channel circuit 402 via preamplifier 404. Preamplifier 404 is operable to amplify the minute analog signals accessed from disk platter 416. In turn, read channel circuit 402 decodes and digitizes the received analog signal to recreate the information originally written to disk platter 416. This data is provided as read data 422 to a receiving circuit. While processing the read data, read channel circuit 402 processes the received signal using a read channel with embedded microcontroller. Such a read channel with embedded microcontroller may be implemented consistent with the circuits and methods disclosed in FIGS. 1-3. A write operation is substantially the opposite of the preceding read operation with write data 424 being provided to read channel circuit 402. This data is then encoded and written to disk platter 416.

It should be noted that storage system 400 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 400, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

In addition, it should be noted that storage system 400 may be modified to include solid state memory that is used to store data in addition to the storage offered by disk platter 416. This solid state memory may be used in parallel to disk platter 416 to provide additional storage. In such a case, the solid state memory receives and provides information directly to read channel circuit 402. Alternatively, the solid state memory may be used as a cache where it offers faster access time than that offered by disk platter 416. In such a case, the solid state memory may be disposed between interface controller 406 and read channel circuit 402 where it operates as a pass through to disk platter 416 when requested data is not available in the solid state memory or when the solid state memory does not have sufficient storage to hold a newly written data set. Based upon the disclosure provided herein, one of ordinary skill in the art will recognize a variety of storage systems including both disk platter 416 and a solid state memory.

Turning to FIG. 5, a wireless communication system 500 or data transmission device including a receiver 504 with a read channel with embedded microcontroller is shown in accordance with some embodiments of the present invention. The transmitter 502 is operable to transmit encoded information via a transfer medium 506 as is known in the art. The encoded data is received from transfer medium 506 by receiver 504. Receiver 504 incorporates a read channel with embedded microcontroller. Such a read channel with embedded microcontroller may be implemented consistent with the circuits and methods disclosed in FIGS. 1-3.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, embodiments of the present invention provide novel systems, devices, methods and arrangements for a read channel with an embedded microcontroller and for processing data with microcontroller based retry features. While detailed descriptions of one or more embodiments of the invention have been given above, various alternatives, modifications, and equivalents will be apparent to those skilled in the art without varying from the spirit of the invention. Therefore, the above description should not be taken as limiting the scope of embodiments of the invention which are encompassed by the appended claims.

What is claimed is:

1. A data processing system comprising:
a data detector operable to apply a data detection algorithm to generate detected values for data sectors;
a data decoder operable to apply a data decode algorithm to a decoder input derived from the detected values to yield decoded values; and
a microcontroller operable to configure the data detector and the data decoder to apply the data detection algorithm and the data decode algorithm.

2. The data processing system of claim 1, further comprising a memory operable to store the data sectors and to provide the data sectors to the data detector, wherein the microcontroller is operable to assemble the data sectors to be provided to the data detector.

3. The data processing system of claim 2, wherein the microcontroller is operable to control a no syncmark retry operation in the data processing system, the control comprising assembling a plurality of different data sectors within a memory window and triggering the data detector and the data decoder to process the plurality of different data sectors.

4. The data processing system of claim 2, wherein the microcontroller is operable to control a targeted symbol flipping retry operation in the data processing system, the control comprising causing the data decoder to selectively change data values and to perform the data decode algorithm to determine whether the changed data values cause the data decode algorithm to succeed.

5. The data processing system of claim 1, further comprising a local interleaver circuit operable to locally interleave the detected values across portions of a sector, wherein the microcontroller is operable to configure the local interleaver circuit.

6. The data processing system of claim 1, further comprising a central memory operable to store data between the data detector and the data decoder, wherein the microcontroller is operable to access the central memory while configuring the data detector and the data decoder to apply the data detection algorithm and the data decode algorithm.

7. The data processing system of claim 1, further comprising a global interleaver circuit operable to globally interleave the detected values across a sector, wherein the microcontroller is operable to configure the global interleaver circuit.

8. The data processing system of claim 1, further comprising a hard decision memory operable to store the decoded values, wherein the microcontroller is operable to access the hard decision memory while configuring the data detector and the data decoder to apply the data detection algorithm and the data decode algorithm.

9. The data processing system of claim 1, further comprising a microcode queue, operable to supply executable instructions to the microcontroller, wherein the microcode queue is programmable to enable variation of functionality of the microcontroller.

10. The data processing system of claim 1, further comprising a scheduler circuit operable to schedule data flow within the data processing system as the data detector applies the data detection algorithm and the data decoder applies the data decode algorithm, wherein the microcontroller is operable to control the scheduler circuit.

11. The data processing system of claim 1, wherein the data detection algorithm comprises a Viterbi algorithm and data decode algorithm comprises a low density parity check algorithm.

12. The data processing system of claim 1, wherein the data detector and the data decoder are implemented as an integrated circuit, and wherein the microcontroller comprises an embedded microcontroller in the integrated circuit.

13. The data processing system of claim 1, wherein the data processing system is incorporated in a storage device.

14. The data processing system of claim 13, wherein the storage device comprises a redundant array of independent disks.

15. The data processing system of claim 1, wherein the data processing system is incorporated in a transmission system.

16. A method of processing data, comprising:
configuring a data detector using a microcontroller;
triggering the data detector using the microcontroller to apply a data detection algorithm to generate detected values for the data;
configuring a data decoder using the microcontroller; and
triggering the data decoder using the microcontroller to apply a data decode algorithm to a decoder input derived from the detected values to yield decoded values.

17. The method of claim 16, wherein configuring the data detector and configuring the data decoder using the microcontroller comprises preparing the data detector and the data decoder for normal processing.

18. The method of claim 16, wherein configuring the data detector and configuring the data decoder using the microcontroller comprises preparing the data detector and the data decoder for a retry operation after normal processing has failed to result in converged data values.

19. The method of claim 18, wherein the retry operation comprises a no syncmark retry operation, and wherein configuring the data detector and configuring the data decoder using the microcontroller further comprises assembling a data sector in an input memory to be processed by the data detector and the data decoder.

20. A storage system comprising:
a storage medium;
a head assembly disposed in relation to the storage medium and operable to provide a sensed signal corresponding to information on the storage medium;
an analog to digital converter circuit operable to sample an analog signal derived from the sensed signal to yield a series of digital samples; and
a data processing system operable to identify correct values for the digital samples, comprising:
a data detector operable to apply a data detection algorithm to generate detected values for data sectors assembled from the series of digital samples;
a data decoder operable to apply a data decode algorithm to a decoder input derived from the detected values to yield decoded values; and
a microcontroller operable to configure the data detector and the data decoder to apply the data detection algorithm and the data decode algorithm.
